(19) United States
(12) Patent Application Publication
(10) Pub. No.: US 2025/0379424 A1
(43) Pub. Date: Dec. 11, 2025

(54) CONTROL CABINET ASSEMBLY WITH FORCED VENTILATION

(71) Applicant: RITTAL GMBH & CO. KG, Herborn (DE)

(72) Inventors: Thorsten HEIMBERG, Schöffengrund (DE); Lena Kristin CORNELIUS, Leun (DE); Jörg KNETSCH, Ehringshausen (DE); Juan Carlos CACHO ALONSO, Braunschweig (DE); Lars Walter NIEBERGALL, Wetzlar (DE)

(21) Appl. No.: 18/876,739

(22) PCT Filed: Jun. 22, 2023
(86) PCT No.: PCT/DE2023/100468

§ 371 Date: Dec. 19, 2024

(30) Foreign Application Priority Data
Jul. 5, 2022 (DE) 10 2022 116 776.3

(51) Int. Cl. H02B 1/56; H05K 7/20

(52) U.S. Cl. CPC H02B 1/565; H05K 7/20318

(57) ABSTRACT

A switchgear cabinet arrangement having at least one switchgear cabinet housing and a cooling device, wherein the cooling device has a refrigerant circuit which has a combustible refrigerant, wherein the refrigerant circuit has an evaporator which is arranged in an inner air circuit of the cooling device and through which air which is received in the switchgear cabinet housing flows, wherein the switchgear cabinet arrangement furthermore comprises a forced ventilation of the switchgear cabinet housing, which forced ventilation has an activated state and otherwise a deactivated state in the event of a detected leakage of the refrigerant circuit, wherein, in the activated state, ambient air of the switchgear cabinet arrangement is conveyed into the switchgear cabinet housing and/or the air which is received in the switchgear cabinet housing is conveyed out of the switchgear cabinet housing.

### CROSS-REFERENCE TO RELATED APPLICATIONS

This application is a U.S. National Phase Application under 35 U.S.C. 371 of International Application No. PCT/DE2023/100468, filed on Jun. 22, 2023, which claims German Patent Application No. 10 2022 116 776.3, filed on Jul. 5, 2022. The entire disclosures of the above applications are incorporated herein by reference.

### BACKGROUND

This section provides background information related to the present disclosure which is not necessarily prior art.

### TECHNICAL FIELD

The invention relates to a switchgear cabinet arrangement having at least one switchgear cabinet housing and a cooling device, wherein the cooling device has a refrigerant circuit which has a combustible refrigerant. The refrigerant circuit has an evaporator which is arranged in an inner air circuit of the cooling device and through which air which is received in the switchgear cabinet housing flows. A switchgear cabinet arrangement of this type is described in DE 10 2018 109 604 A1.

### Discussion

Directive 2006/42/EC (Machine Directive) requires that there is no risk of explosion and fire from gases which are used in a machine, wherein it is to be assumed that individual components fail. If, therefore, in the case of a switchgear cabinet cooling device, a refrigerant-conducting part has an assumed leakage, it is to be assumed that combustible gas (refrigerant) passes into the switchgear cabinet and can ignite there on internal fittings which ignite arcs during operation. Without a safety function which reliably prevents this, switchgear cabinet cooling devices which use combustible refrigerants cannot meet the machine directive or can be operated with the necessary safety for the end user.

The switchgear cabinet arrangements which are known from the prior art have the disadvantage that they are comparatively complex to implement since, for example, different, actively driven closing members are required and have to be actuated in the event of a detected leakage and in the event of entry of a combustible refrigerant into the interior of the switchgear cabinet.

### SUMMARY

This section provides a general summary of the disclosure and is not a comprehensive disclosure of its full scope or all of its features.

It is therefore one aspect of the invention to develop the switchgear cabinet arrangement which is described at the outset in such a way that it can be implemented using simple technical means and is accordingly inexpensive to provide.

Accordingly, in the case of a switchgear cabinet arrangement of the type which is described at the outset, it is provided that it has a forced ventilation of the switchgear cabinet housing, which forced ventilation has an activated state and otherwise a deactivated state in the event of a detected leakage of the refrigerant circuit of the cooling device. In the activated state, ambient air of the switchgear cabinet arrangement is intended to be conveyed into the switchgear cabinet housing and/or the air which is received in the switchgear cabinet housing is intended to be conveyed out of the switchgear cabinet housing.

The refrigerant circuit can be, for example, a constituent part of a refrigerating machine and/or of a passive refrigerant circuit, for example a refrigerant circuit in natural circulation, driven by a geodetic height difference, for example a heat pipe. Accordingly, the refrigerant circuit can be configured as an active refrigerant circuit or as a passive circuit. In principle, the invention is not restricted to the use of certain methods for producing refrigeration. In particular, all means which relate to the forced ventilation according to the invention can be configured independently of the refrigerant circuit and, in particular, it is not necessary to monitor the refrigerant circuit itself in order to infer a leakage of said refrigerant circuit.

The refrigerant circuit can have a condenser in an outer air circuit of the cooling device, which outer air circuit is fluidically separated from the inner air circuit, wherein ambient air which is conducted through the outer air circuit flows through the condenser.

In the deactivated state, the forced ventilation can be fluidically closed via an adjustable closing member. In this case, the interior of the switchgear cabinet housing can be fluidically separated from the ambient air of the switchgear cabinet housing. In particular, there should be no air exchange between the inner air circuit and the outer air circuit.

The forced ventilation can have at least one fan, by means of which ambient air is transported into the interior of the switchgear cabinet housing in the activated state of the forced ventilation. Alternatively, the fan can be configured to blow out the air received in the switchgear cabinet housing into the surroundings.

The forced ventilation can have at least one air guide channel between the surroundings of the switchgear cabinet housing and the interior of the switchgear cabinet housing. The air guide channel can be closed via a closing member, preferably a non-return flap, in the deactivated state of the forced ventilation. For this purpose, the non-return flap can be pretensioned into its closed position, so that an air volume flow opening the non-return flap does not occur when the fan is deactivated.

The at least one air guide channel can be a constituent part of the cooling device or can be configured independently of the cooling device. If the air guide channel is a constituent part of the cooling device, at least one further air guide channel can likewise be a constituent part of the cooling device or a constituent part of the switchgear cabinet housing. The two air guide channels can accordingly be configured to provide an air supply into the interior of the switchgear cabinet housing and an air discharge from the interior into the surroundings of the switchgear cabinet housing. At least one of the air guide channels can accordingly have a fan.

The cooling device can have two air guide channels, of which at least one air guide channel has a fan. In this case, at least one of the air guide channels can have a closing member, preferably a non-return flap. The closing member can be permeable only in an air flow direction generated by the fan. The closing member can be pretensioned in particular into a closed position, in which it closes the relevant air guide channel when the fan is deactivated. Accordingly, the closing member opens when the fan is activated. Thus, the closing member can be openable in the flow direction generated by the fan and close the air guide channel in the opposite direction. In the permeable direction, the closing member, for example a non-return flap, can open due to the dynamic pressure generated when the fan is activated.

The switchgear cabinet arrangement can have at least one refrigerant sensor for the detection of a combustible refrigerant in the air received in the interior of the switchgear cabinet housing. The refrigerant sensor can be arranged in principle at any desired point of the switchgear cabinet arrangement at which the sensor is exposed in the event of a leakage of the refrigerant circuit to the air in the interior of the switchgear cabinet housing which is acted upon by the evaporating refrigerant. This can be on any desired side of the switchgear cabinet housing facing the interior. Alternatively, the refrigerant sensor can also be arranged on an outer side of the cooling device facing the interior. Furthermore, the refrigerant sensor can be arranged, for example, in the cooling device, for example in the inner air circuit of the cooling device. Furthermore alternatively, the refrigerant sensor can be a component of a filter fan of the switchgear cabinet arrangement and can be arranged either on a side of the filter fan facing the interior or in an internal region of the filter fan which is acted upon by the air received in the interior of the switchgear cabinet housing. In particular, for the purpose of redundancy, a plurality of the abovementioned refrigerant sensors can be provided, wherein preferably at least two of the redundant refrigerant sensors are arranged at different ones of the abovementioned installation positions of the switchgear cabinet arrangement.

The switchgear cabinet arrangement can have at least one single-channel refrigerant sensor which is sensitive to at least one combustible refrigerant, for example R32, R1234yf, r1234ze, propane or butane.

If the switchgear cabinet arrangement has at least two of the abovementioned refrigerant sensors, it can be provided that the at least two refrigerant sensors are sensitive to at least one identical combustible refrigerant and in this case the two refrigerant sensors can be configured to output their respective sensor signal in a single-channel manner, preferably via the same channel.

The at least one refrigerant sensor can be configured to forward the detection of a refrigerant in the air received in the interior of the switchgear cabinet housing to a control and regulation unit for initiating a safety measure for lowering a concentration of the refrigerant in the air received in the interior of the switchgear cabinet. In this case, the control and regulation unit can be arranged outside or inside the switchgear cabinet arrangement, for example outside the switchgear cabinet housing and outside the cooling device, and can be connected via a signal interface to the at least one refrigerant sensor for the signal transmission. The control and regulation unit can be configured to transfer the forced ventilation of the switchgear cabinet housing from the deactivated state into the activated state.

The at least one refrigerant sensor can be configured to forward the detection of a refrigerant in the air received in the interior of the switchgear cabinet housing to a control and regulation unit arranged in the cooling device. In this case, the cooling device can be configured to initiate a safety measure for lowering a concentration of the refrigerant in the air received in the interior of the switchgear cabinet, preferably to transfer the forced ventilation of the switchgear cabinet housing from the deactivated state into the activated state.

The at least one refrigerant sensor can be arranged in an air outlet flow of the inner air circuit from the cooling device into the interior of the switchgear cabinet housing or in an air inlet flow of the outer air circuit from the surroundings of the switchgear cabinet housing into the cooling device.

The cooling device can have at least one additional fan, by means of which ambient air from the surroundings of the switchgear cabinet arrangement is sucked into a housing of the cooling device and blown into the interior of the switchgear cabinet housing.

The cooling device can be configured to be deactivated upon detection of a combustible refrigerant by the at least one refrigerant sensor, so that at least one compressor of the cooling device is deactivated. The switchgear cabinet arrangement can furthermore have a safety device which is configured to avoid an accidental restart of the compressor. The at least one fan can have a refrigerant sensor which is acted upon by the air received in the switchgear cabinet housing, wherein the at least one fan is configured for the ventilation or venting of the switchgear cabinet housing.

By means of at least one fan, the air received in the switchgear cabinet housing can be blown out into the surroundings of the switchgear cabinet housing and air from the surroundings of the switchgear cabinet housing can be blown into the switchgear cabinet housing.

The switchgear cabinet arrangement can have at least one further fan which is configured as an inlet or outlet filter fan. Preferably, the at least one fan and the at least one further fan are configured as fans with opposite flow direction with respect to the interior of the switchgear cabinet housing.

The at least one fan can be arranged in an aperture in a vertical or horizontal wall of the switchgear cabinet housing and can be configured in particular separately from the cooling device.

The refrigerant sensor can be arranged either in a housing of the at least one fan on a circuit board of a controller of the fan or on an outer side of the at least one fan and can be connected in a wired or wireless manner to a controller of the fan. Alternatively, the refrigerant sensor can be fastened in the interior of the switchgear cabinet housing to the switchgear cabinet housing and can be connected via a wireless or wired signal interface to the controller of the fan.

The fan can have an alarm output which is configured to output an alarm signal when the fan is transferred from the deactivated state into the activated state. The alarm signal which is provided via the alarm output can be used, for example, for the cascading actuation of at least one further fan.

The fan can have an alarm input which is configured to trigger the forced ventilation in the event of an incoming alarm signal. The alarm input can be connected in a wireless or wired manner to an alarm output of a further fan of the switchgear cabinet arrangement for the transmission of the alarm signal.

The forced ventilation can have an air guide in a base of the switchgear cabinet housing, via which air guide the interior of the switchgear cabinet housing is fluidically connected via the base of the switchgear cabinet housing to the surroundings of the switchgear cabinet housing.

The air guide in the base can have at least one fan, by means of which ambient air is transported into the interior of the switchgear cabinet housing in the activated state of the forced ventilation or the air received in the interior of the switchgear cabinet housing is transported out of the interior into the surroundings.

The base can be separated from the interior of the switchgear cabinet housing via at least one base plate. For this purpose, the at least one base plate can be air-permeable, for example perforated, at least in sections. The base plate can accordingly form a fluidic transition between the interior of the switchgear cabinet housing and the air guide in the base. Alternatively or additionally, at least two base plates can be formed solidly, i.e. without apertures, and can be arranged at a distance from one another, for example with an air-permeable cable bushing formed between the base plates, which leads into the air guide in the base.

The fluidic transition can be an aperture in a base plate, in which aperture a fan is preferably, but not necessarily, mounted. By means of the fan, either the air received in the interior of the switchgear cabinet housing can be discharged through the air guide into the surroundings or ambient air can be introduced into the interior of the switchgear cabinet housing.

The air-permeable base plate can be formed at least in sections as a cable bushing through the base plate and/or as an air-permeable nonwoven, for example a filter substrate.

A fan can be arranged in an aperture in a flat part of the switchgear cabinet housing, by means of which fan either ambient air is blown into the interior of the switchgear cabinet housing or the air received in the interior is discharged into the surroundings of the switchgear cabinet arrangement. In this case, a pressure compensation can be provided via the air guide, wherein either ambient air is guided into the interior or the air received in the interior is discharged into the surroundings.

The switchgear cabinet housing can have at least one air inlet or one air outlet, wherein the air inlet or air outlet is preferably configured as an aperture in at least one flat part. The flat part can be, for example, a side wall, a rear wall, a door element or a roof element of the switchgear cabinet housing.

In one embodiment, at least one fan is arranged in the aperture, wherein the switchgear cabinet housing or the base has at least one further air inlet or air outlet, preferably at least one further aperture.

At least one refrigerant sensor can be arranged for the detection of a combustible refrigerant in the base, for example in a housing of a fan of the forced ventilation and/or in the air guide, or on an upper side of the base facing the switchgear cabinet interior, for example on a base plate of the base, or above the base in the switchgear cabinet housing.

The switchgear cabinet arrangement can furthermore have at least one refrigerant sensor which is arranged in the air guide or is acted upon by the air guide with the air guided through the air guide. In this case, the air received in the interior of the switchgear cabinet housing can preferably be discharged via the air guide into the surroundings of the switchgear cabinet arrangement.

The at least one refrigerant sensor can be a constituent part of the fan and be exposed on a side of a housing of the fan facing the interior of the switchgear cabinet housing. Alternatively or additionally, the refrigerant sensor or a further refrigerant sensor can be arranged in the interior of the switchgear cabinet housing and can be connected via a wired or wireless signal interface to a control and regulation unit for transferring the forced ventilation from the deactivated state into the activated state. The control and regulation unit can be a constituent part of the fan or can be configured independently of the fan.

The at least one fan can be arranged in an aperture in the roof of the switchgear cabinet housing, wherein the fan is configured to transport the air received in the interior of the switchgear cabinet housing out of the switchgear cabinet housing. In this case, the switchgear cabinet housing can preferably have at least one air inlet, preferably an aperture in a flat part of the switchgear cabinet housing, in a lower region of the switchgear cabinet housing.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

Further details of the invention will be explained with reference to the figures below. In the figures:

FIG. 1 shows a schematic cross-sectional view of an exemplary embodiment of a switchgear cabinet arrangement according to the invention;

FIG. 2 shows a schematic illustration of a further embodiment of a switchgear cabinet arrangement according to the invention;

FIG. 3 shows a schematic illustration of yet a further embodiment of a switchgear cabinet arrangement according to the invention;

FIG. 4 shows a schematic illustration of yet a further embodiment of a switchgear cabinet arrangement according to the invention;

FIG. 5 shows a schematic illustration of yet a further embodiment of a switchgear cabinet arrangement according to the invention;

FIG. 6 shows a schematic illustration of yet a further embodiment of a switchgear cabinet arrangement according to the invention;

FIG. 7 shows in a schematic illustration, an exemplary embodiment of a filter fan;

FIG. 8 shows yet a further embodiment of a filter fan; and

FIG. 9 shows yet a further embodiment of a filter fan.

### DETAILED DESCRIPTION

Example embodiments will now be described more fully with reference to the accompanying drawings.

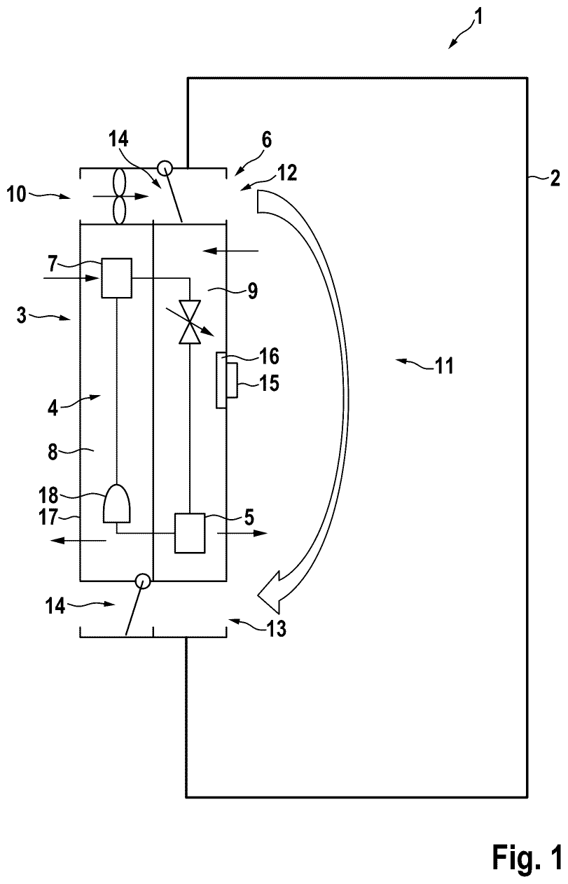

The embodiment of a switchgear cabinet arrangement 1 according to the invention which is illustrated in FIG. 1 is distinguished in that all means which relate to the forced ventilation according to the invention are integrated into the cooling device 2, in particular a first and a second air guide channel 12, 13, which in each case have a non-return flap 14 and a fan 10 which is integrated into the first air guide channel 12. Here, it is provided that the forced ventilation 6 is configured independently of both the inner air circuit 9 and the outer air circuit 8 of the cooling device 3. In particular, there are no fluidic transitions between the forced ventilation 6, in particular the air guide channels 12, 13, and the inner air circuit 9 and the outer air circuit 8.

The refrigerant sensor 15 which is provided for the detection of a leakage by enrichment of a combustible refrigerant in the air received in the interior 11 of the switchgear cabinet housing 2 is also arranged on an outer side of the cooling device 3 facing the interior 11, via which outer side the cooling device 2 projects through a vertical side wall or a rear wall or a door element into the switchgear cabinet housing 2, so that the inner air circuit 9 is fluidically connected to the air received in the interior 11. The cooling device 3 has, in the known manner, a refrigerating machine, with an evaporator 5 in the inner air circuit 9, a condenser 7 in the outer air circuit 8 and a compressor 18 and an expansion valve. Alternatively or additionally, the refrigerant sensor 15 or a further refrigerant sensor 15 can be arranged in the interior of the cooling device 3, for example in an air guide of the inner air circuit 9, for example in the region of an opening via which the inner air circuit 9 opens into the interior 11 of the switchgear cabinet housing 2.

If the enrichment of the combustible refrigerant in the air received in the interior 11 is detected above a threshold value via the refrigerant sensor 15, a corresponding sensor signal can be received by the control and regulation unit 16, evaluated and converted into a corresponding control signal for triggering the forced ventilation according to the invention. In the present case, the detection of the threshold value being exceeded would lead to the fan 10 starting up. The fan 10 in the air guide channel 12 is configured to blow ambient air from the surroundings of the switchgear cabinet arrangement 1 through the air guide channel 12 into the interior 11 of the switchgear cabinet housing 2. The closing member 14 is configured in the present case as a non-return flap which can be opened in the flow direction generated by the fan 10. The non-return flap has a pretension into its closed position, so that the first air guide channel 12 is closed when the fan 10 is deactivated. Analogously, the non-return flap 14 is pretensioned into its closed position in the second air guide channel 13. If an overpressure is generated in the switchgear cabinet interior 11 via the fan 10 by opening the non-return flap 14 in the first air guide channel 12, the non-return flap 14 opens in the second air guide channel 13 counter to its pretension, so that the overpressure in the switchgear cabinet housing 2 can be reduced. In this case, the air received in the switchgear cabinet interior 11 and charged with the combustible refrigerant is blown out via the second air guide channel 13, consequently through the housing 17 of the cooling device 3, into the surroundings of the switchgear cabinet arrangement 1, so that the exceeding of a threshold value, which is critical for safety reasons, for the concentration of the combustible refrigerant in the atmosphere in the interior 11 of the switchgear cabinet housing 2 is avoided.

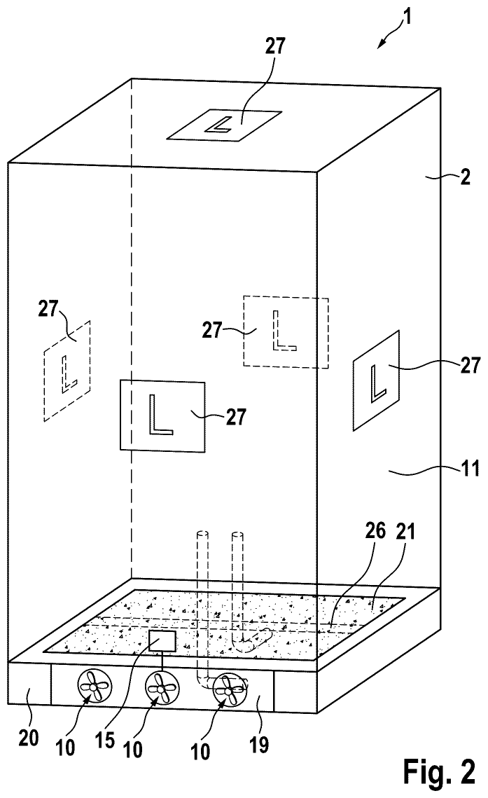

In the embodiment shown in FIG. 2, it is provided that the switchgear cabinet housing 2 stands on a base 20. This can be a customary switchgear cabinet base on which the frame of the switchgear cabinet housing is set up. The forced ventilation has in the present case an air guide 19 in the base 20, via which air guide the interior 11 of the switchgear cabinet housing 2 is fluidically connected to the surroundings of the switchgear cabinet arrangement 1. In the present case, three fans 10 are arranged in the base 20, in particular as a constituent part of the air guide 19. Depending on the embodiment, a different number of fans 10 can be expedient. The fans 10 are configured either to suck ambient air into the air guide 19 and to blow it via base plates 21 into the interior 11 or, in the opposite air guide direction, to blow out the air received in the interior 11 through the base plates 21 and the air guide 19 into the surroundings. The fans 10 can be configured as filter fans and close off the air guide 19 with respect to the surroundings of the switchgear cabinet arrangement 1. The base plates 21 can be fluidically permeable, for example perforated, and form the termination of the air guide 19 directed towards the interior 11.

A refrigerant sensor 15 can be provided in the region of the base, in particular of the base plates. The refrigerant sensor can also be arranged in the air guide, for example in an air guide channel. Alternatively, the refrigerant sensor 15 can be arranged above the base in the switchgear cabinet housing, for example on an inner side of a flat part of the switchgear cabinet housing 2 facing the interior.

The base 20 furthermore has a cable bushing 26 which is formed fluidically separately from the air guide 19. Via the cable bushing 26, lines from the surroundings of the switchgear cabinet arrangement 1 can be introduced through the base 19 into the interior 11.

The switchgear cabinet housing 2 has an aperture 20 on its flat parts, in particular on its side walls, on its rear wall, on its front wall or door, or on its roof. It is not necessarily necessary that, as illustrated in FIG. 2, all of the flat parts have a respective aperture 20. Fewer passages 20 are also conceivable. The apertures 20 can serve for an additional fresh air supply or for a discharge of air acted upon by refrigerant, in particular for the pressure compensation when the fans 10 of the air guide 19 are activated in the base 20. To increase the air volume flow, at least one of the apertures 20 can have an additional fan 27, for example a filter fan.

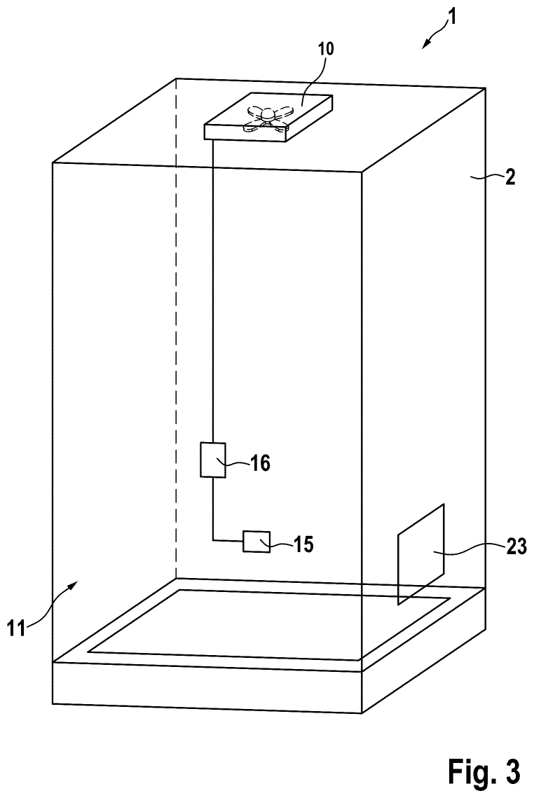

In the embodiment shown in FIG. 3, the forced ventilation has a fan 10 in the roof of the switchgear cabinet housing 2 and an air inlet or air outlet 23 in a side wall of the housing 2. Arranged in the interior of the switchgear cabinet housing is a refrigerant sensor 15 which is connected via a signal line to the control and regulation unit 16. The control and regulation unit 16 is configured to activate the fan 10 when a threshold value for a refrigerant concentration in the air received in the interior 11 of the switchgear cabinet housing 2 is exceeded by the refrigerant sensor 15. In the embodiments described above, the fan 10 can be configured either to blow ambient air into the interior 11, such that the air inlet or air outlet 23 actually has the function of an air outlet, or to blow out the air received in the interior 11 from the switchgear cabinet housing 2, such that the air inlet or air outlet 23 has the function of an air inlet.

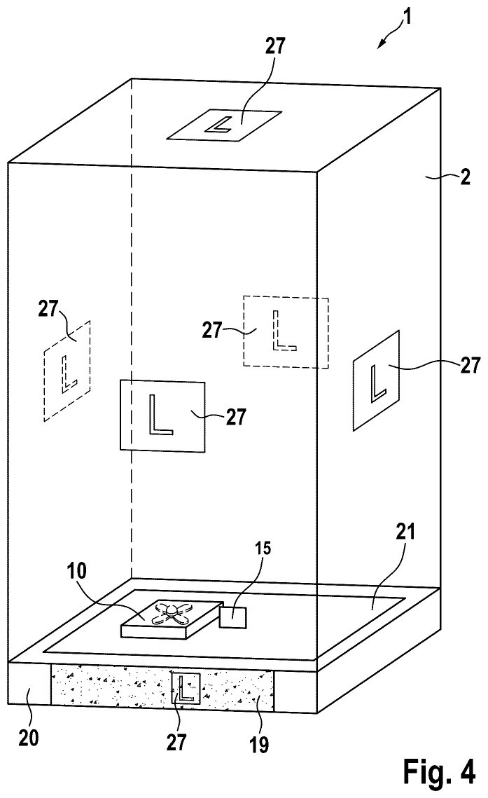

In the embodiment illustrated in FIG. 4, in a departure from the embodiment according to FIG. 2, at least one aperture in a base plate, into which at least one fan is inserted, is provided for the air transition between the air guide 19 in the base 20 instead of perforated base plates. The fan 10 furthermore has the refrigerant sensor 15. In a departure therefrom, however, the refrigerant sensor 15 can also not be a constituent part of the fan 10 and can be connected to the fan 10, for example, in the manner described with reference to FIG. 3. In the embodiment described in FIG. 4, accordingly, the control and regulation unit (not illustrated) is a constituent part of the fan 10 and is realized as a compact structural unit with the fan 10. Accordingly, the air guide in turn has an air inlet or air outlet 23 at its end facing the surroundings of the switchgear cabinet arrangement 1, which air inlet or air outlet can be, for example, an aperture of the base 20 which is closed by a filter insert, for example a filter substrate.

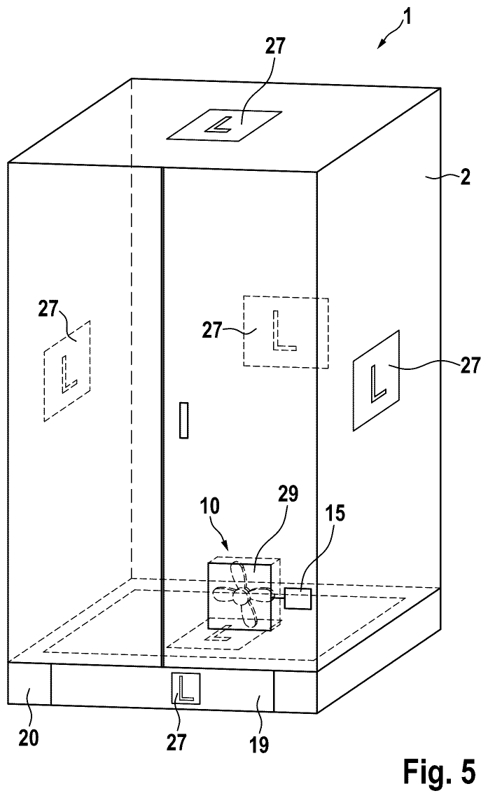

In a departure from the embodiment shown in FIG. 4, the fan 10 in the embodiment shown in FIG. 5 is arranged in an aperture in a door element of the switchgear cabinet housing 2.

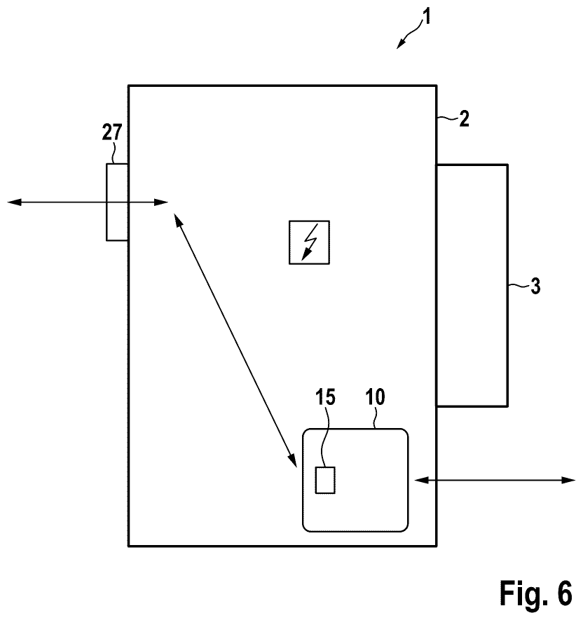

FIG. 6 shows, analogously to the embodiment according to FIG. 3, a variant of the invention in which all the components which relate to the forced ventilation according to the invention are realized in a fan 10 and by an additional air inlet or air outlet 23. This embodiment is therefore suitable in particular as a retrofit solution if the cooling device 3 is not to be changed, in particular not to be exchanged. In particular, in the embodiment, the refrigerant sensor is a constituent part of the fan 10, which can be configured in particular as a filter fan which is inserted in an aperture of a flat part of the switchgear cabinet housing. An additional air inlet or air outlet 23 is necessary for the pressure compensation. The air inlet or air outlet is also preferably closed by a filter mat so that the relevant IP protection classes can be complied with.

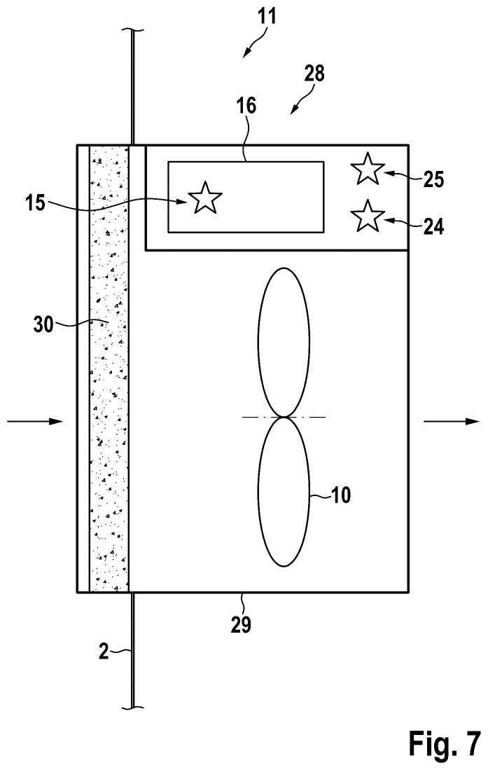

The embodiments 7 to 9 describe in particular a fan 10 which is received in a housing 28, including the control and regulation unit 16 which is necessary for the actuation in the event of a leakage, in a uniform housing 28. The fan 10 can be configured, for example, as a filter fan which, as illustrated, is mounted in an aperture of the switchgear cabinet housing 2. The switchgear cabinet housing 2 has, on an air inlet side, a filter element 30, for example a nonwoven, which closes off the air inlet to the surroundings. In the embodiment according to FIG. 7, the refrigerant sensor 15 is a constituent part of the regulation and control unit 16, for example arranged on a circuit board thereof. For the cascading of the signal of the sensor 15, an alarm output is provided in the housing 28 for forwarding an alarm signal which has been generated from the signal of the sensor 15 by the regulation and control unit 16, for example in order to actuate further filter fans which themselves do not have a sensor 15 and no regulation and control electronics in this respect. Likewise, an alarm input 25 can be provided in order to actuate the fan 10 if the sensor 15 which is assigned to the fan 10 itself has not detected a leakage, but another sensor (not illustrated) of another fan or a sensor which is arranged at another point in the switchgear cabinet housing has already detected a leakage, for example because the other sensor is arranged closer to the location of the leakage than the sensor 15 which is illustrated in FIG. 7.

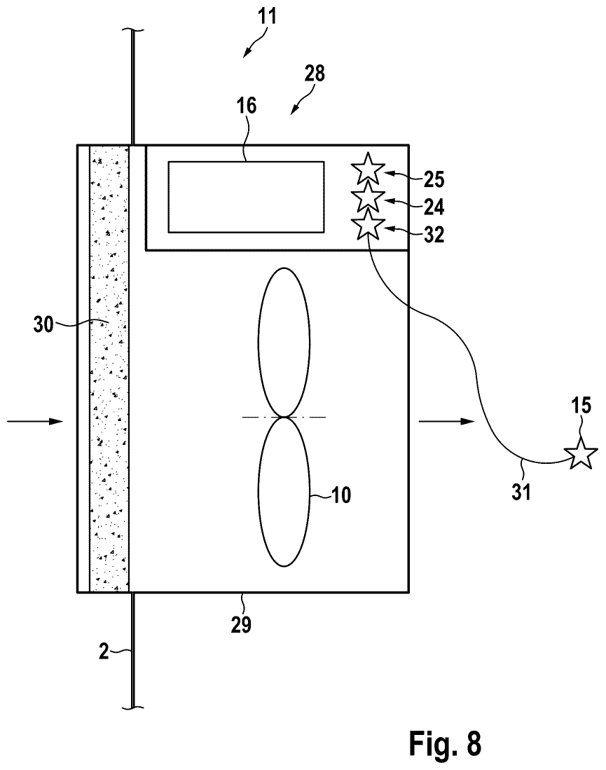

In the embodiment illustrated in FIG. 8, in a departure from the embodiment according to FIG. 7, the sensor 15 is arranged outside the housing of the inlet or outlet filter fan 28, for example at any desired point in the interior 11 of the switchgear cabinet housing 2. A connection point 32 of the inlet or outlet filter fan 28 is connected in a wired or wireless manner to the sensor 15 in the interior 11.

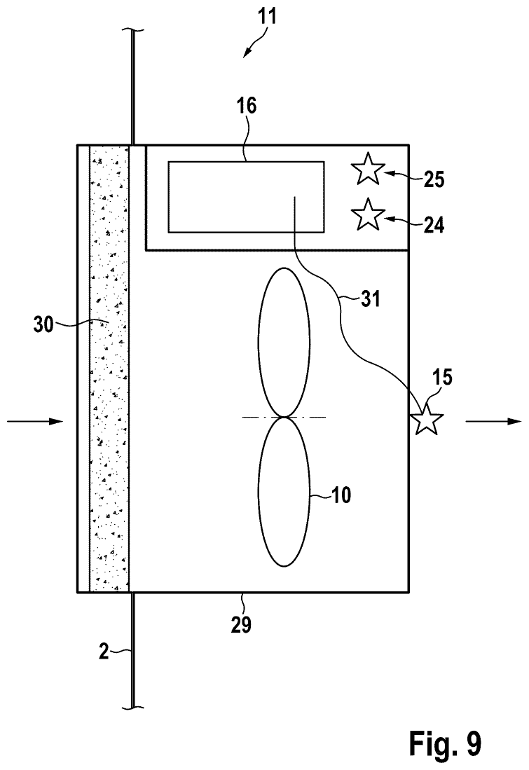

The embodiment according to FIG. 9 shows a variant in which the sensor 15 is directly connected to the control and regulation unit, for example fixedly wired to a circuit board of the control and regulation unit 16.

The features of the invention which are disclosed in the above description, in the drawings and in the claims can be essential both individually and in any desired combination for the realization of the invention.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-36. (canceled)

37. A switchgear cabinet arrangement having at least one switchgear cabinet housing and at least one refrigeration appliance, comprising wherein the refrigeration appliance has a refrigerant circuit which has a combustible refrigerant, wherein the refrigerant circuit has an evaporator which is arranged in an internal air circuit of the refrigeration appliance, which is separated fluidically from an external air circuit of the cooling device and through which air which is received in the switchgear cabinet housing flows, wherein the switchgear cabinet arrangement furthermore comprises a forced ventilation of the switchgear cabinet housing, which forced ventilation has an activated state and otherwise a deactivated state in the event of a detected leakage of the refrigerant circuit, wherein, in the activated state, ambient air of the switchgear cabinet arrangement is conveyed into the switchgear cabinet housing and/or the air which is received in the switchgear cabinet housing is conveyed out of the switchgear cabinet housing, wherein the forced ventilation is formed independently of both the inner air circuit and the outer air circuit of the cooling device.

38. The switchgear cabinet arrangement according to claim 37, in which the refrigerant circuit is a constituent part of a refrigerating machine and/or a heat pipe.

39. The switchgear cabinet arrangement according to claim 37, in which the refrigerant circuit has a condenser in an external air circuit of the refrigeration appliance, which external air circuit is fluidically separated from the internal air circuit, wherein ambient air which is conducted through the external air circuit flows through the condenser.

40. The switchgear cabinet arrangement according to claim 37, in which, in the deactivated state, the forced ventilation is fluidically closed via an adjustable closing member, wherein the interior of the switchgear cabinet housing is fluidically separated from the surroundings of the switchgear cabinet housing.

41. The switchgear cabinet arrangement according to claim 37, in which the forced ventilation has at least one fan, by means of which ambient air is transported into the interior of the switchgear cabinet housing in the activated state of the forced ventilation.

42. The switchgear cabinet arrangement according to claim 37, in which the forced ventilation has at least one air guide channel between the surroundings of the switchgear cabinet housing and the interior of the switchgear cabinet housing, which air guide channel is closed via a closing member, preferably a non-return flap, in the deactivated state of the forced ventilation.

43. The switchgear cabinet arrangement according to claim 42, in which the at least one air guide channel is a constituent part of the refrigeration appliance, wherein at least one further air guide channel is likewise a constituent part of the refrigeration appliance or a constituent part of the switchgear cabinet housing.

44. The switchgear cabinet arrangement according to claim 43, in which the refrigeration appliance has two air guide channels, of which at least one air guide channel has a fan, and wherein at least one of the air guide channels has a closing member, preferably a non-return flap, which is permeable only in an air flow direction generated by the fan.

45. The switchgear cabinet arrangement according to claim 37, which has at least one refrigerant sensor for the detection of a combustible refrigerant in the air received in the interior of the switchgear cabinet housing.

46. The switchgear cabinet arrangement according to claim 45, in which the switchgear cabinet arrangement has at least one single-channel refrigerant sensor which is sensitive to at least one combustible refrigerant, for example R32, R1234yf, r1234ze, propane or butane.

47. The switchgear cabinet arrangement according to claim 45, in which the switchgear cabinet arrangement has at least two refrigerant sensors for the detection of a combustible refrigerant in the air received in the interior of the switchgear cabinet housing, wherein the at least two refrigerant sensors are sensitive to at least one identical combustible refrigerant, for example R32, R1234yf, r1234ze, propane or butane, wherein the two refrigerant sensors are preferably configured to output their respective sensor signal in a single-channel manner, preferably via the same channel.

48. The switchgear cabinet arrangement according to claim 45, in which the at least one refrigerant sensor is configured to forward the detection of a refrigerant in the air received in the interior of the switchgear cabinet housing to a control and regulation unit for the initiation of a safety measure for lowering a concentration of the refrigerant in the air received in the interior of the switchgear cabinet, wherein the control and regulation unit is arranged inside or outside, preferably outside, the switchgear cabinet arrangement, for example outside the switchgear cabinet housing and outside the cooling device, and is connected via a signal interface to the at least one refrigerant sensor for the signal transmission, wherein the control and regulation unit is configured to transfer the forced ventilation of the switchgear cabinet housing from the deactivated state into the activated state.

49. The switchgear cabinet arrangement according to claim 45, in which the at least one refrigerant sensor is configured to forward the detection of a refrigerant in the air received in the interior of the switchgear cabinet housing to a control and regulation unit arranged in the cooling device, wherein the cooling device is configured to initiate a safety measure for lowering a concentration of the refrigerant in the air received in the interior of the switchgear cabinet, preferably to transfer the forced ventilation of the switchgear cabinet housing from the deactivated state into the activated state.

50. The switchgear cabinet arrangement according to claim 45, in which the at least one refrigerant sensor is arranged in an air outlet flow of the internal air circuit from the cooling device into the interior of the switchgear cabinet housing or in an air inlet flow of the internal air circuit from the interior of the switchgear cabinet housing into the cooling device.

51. The switchgear cabinet arrangement according to claim 37, in which the cooling device has at least one additional fan, by means of which ambient air from the surroundings of the switchgear cabinet arrangement is sucked into a housing of the cooling device and blown into the interior of the switchgear cabinet housing.

52. The switchgear cabinet arrangement according to claim 45, in which the cooling device is configured to be deactivated upon detection of a combustible refrigerant by the at least one refrigerant sensor, so that at least one compressor of the cooling device is deactivated, wherein the switchgear cabinet arrangement furthermore has a safety device which is configured to avoid an accidental restart of the compressor.

53. The switchgear cabinet arrangement according to claim 41, in which the at least one fan has a refrigerant sensor which is acted upon by the air received in the switchgear cabinet housing, wherein the at least one fan is configured for the ventilation or venting of the switchgear cabinet housing.

54. The switchgear cabinet arrangement according to claim 53, in which by means of the at least one fan the air received in the switchgear cabinet housing is blown out into the surroundings of the switchgear cabinet housing or ambient air of the switchgear cabinet housing is blown into the switchgear cabinet housing.

55. The switchgear cabinet arrangement according to claim 53, which has at least one further fan which is configured as an inlet or outlet filter fan, wherein preferably the at least one fan and the at least one further fan are configured as fans with opposite flow direction with respect to the interior of the switchgear cabinet housing.

56. The switchgear cabinet arrangement according to claim 53, in which the at least one fan is arranged in an aperture in a vertical or horizontal wall of the switchgear cabinet housing and is configured in particular separately from the cooling device.

57. The switchgear cabinet arrangement according to claim 53, in which the refrigerant sensor is arranged either in a housing of the at least one fan on a circuit board of a controller of the fan, or is arranged on an outer side of the at least one fan and is connected in a wired or wireless manner to a controller of the fan, or is fastened in the interior of the switchgear cabinet housing to the switchgear cabinet housing and is connected via a wireless or wired signal interface to the controller of the fan.

58. The switchgear cabinet arrangement according to claim 53, in which the fan has an alarm output which is configured to output an alarm signal when the fan is transferred from the deactivated state into the activated state.

59. The switchgear cabinet arrangement according to claim 53, in which the fan has an alarm input which is configured to trigger the forced ventilation in the event of an incoming alarm signal, wherein the alarm input is connected in a wireless or wired manner to an alarm output of a further fan of the switchgear cabinet arrangement for the transmission of the alarm signal.

60. The switchgear cabinet arrangement according to claim 37, in which the forced ventilation has an air guide in a base of the switchgear cabinet housing, via which air guide the interior of the switchgear cabinet housing is fluidically connected via the base of the switchgear cabinet housing to the surroundings of the switchgear cabinet housing.

61. The switchgear cabinet arrangement according to claim 60, in which the air guide in the base has at least one fan, by means of which ambient air is transported into the interior of the switchgear cabinet housing in the activated state of the forced ventilation or the air received in the interior of the switchgear cabinet housing is transported out of the interior into the surroundings.

62. The switchgear cabinet arrangement according to claim 60, in which the base is separated from the interior of the switchgear cabinet housing via at least one base plate, wherein the at least one base plate is air-permeable, for example perforated, at least in sections, wherein the base plate is a fluidic transition between the interior of the switchgear cabinet housing and the air guide in the base.

63. The switchgear cabinet arrangement according to claim 60, in which the fluidic transition is an aperture in the base plate, in which aperture a fan is preferably mounted, by means of which fan either the air received in the interior of the switchgear cabinet housing is discharged through the air guide into the surroundings or ambient air is introduced into the interior of the switchgear cabinet housing.

64. The switchgear cabinet arrangement according to claim 62, in which the air-permeable base plate is formed at least in sections as a cable bushing through the base plate and/or as an air-permeable nonwoven, for example a filter substrate.

65. The switchgear cabinet arrangement according to claim 61, in which a fan is arranged in an aperture in a flat part of the switchgear cabinet housing, by means of which fan either ambient air is blown into the interior of the switchgear cabinet housing or the air received in the interior is discharged into the surroundings of the switchgear cabinet arrangement, wherein a pressure compensation is provided via the air guide, wherein either ambient air is guided into the interior or the air received in the interior is discharged into the surroundings.

66. The switchgear cabinet arrangement according to claim 58, wherein the switchgear cabinet housing has at least one air inlet or outlet, preferably an aperture in at least one flat part, for example in a side wall, a rear wall, a door element, or a roof element of the switchgear cabinet housing.

67. The switchgear cabinet arrangement according to claim 63, in which the at least one fan is arranged in the aperture, wherein the switchgear cabinet housing or the base has at least one further air inlet or air outlet, preferably at least one further aperture.

68. The switchgear cabinet arrangement according to one of claim 45, in which at least one refrigerant sensor for the detection of a combustible refrigerant is arranged in the base, for example in a housing of a fan of the forced ventilation and/or in the air guide, or on an upper side of the base facing the switchgear cabinet interior, for example on a base plate of the base, or above the base in the switchgear cabinet housing.

69. The switchgear cabinet arrangement according to claim 45, which furthermore has at least one refrigerant sensor which is arranged in the air guide or is acted upon by the air guide with the air guided through the air guide, wherein preferably the air received in the interior of the switchgear cabinet housing is discharged via the air guide into the surroundings of the switchgear cabinet arrangement.

70. The switchgear cabinet arrangement according to claim 45, in which the at least one refrigerant sensor is a component of the fan and is exposed on a side of a housing of the fan facing the interior of the switchgear cabinet housing, or in which the at least one refrigerant sensor is arranged in the interior of the switchgear cabinet housing and is connected via a wired or wireless signal interface to a control and regulating unit for transferring the forced ventilation from the deactivated state into the activated state, wherein the control and regulating unit can be a component of the fan or can be formed independently of the fan.

71. The switchgear cabinet arrangement according to claim 37, in which at least one fan is arranged in an aperture in the roof of the switchgear cabinet housing, by means of which the air received in the interior of the switchgear cabinet housing is transported out of the switchgear cabinet housing, wherein the switchgear cabinet housing preferably has at least one air inlet, preferably an aperture in a flat part of the switchgear cabinet housing, in a lower region of the switchgear cabinet housing.

72. The switchgear cabinet arrangement according to claim 37, in which the interiors of a plurality of switchgear cabinet housings are fluidically connected to one another, wherein at least one of the switchgear cabinet housings has no means for monitoring the presence of a refrigerant in the air received in the interior of the respective switchgear cabinet housing.
